(19) United States
(12) Patent Application Publication
(10) Pub. No.: US 2025/0219346 A1
(43) Pub. Date: Jul. 3, 2025

(54) SPECTRAL FEATURE CONTROL APPARATUS

(71) Applicant: CYMER, LLC, San Diego, CA (US)

(72) Inventors: Jian Zhao, San Diego, CA (US); Walter Dale Gillespie, Poway, CA (US)

(21) Appl. No.: 18/875,946

(22) PCT Filed: Aug. 30, 2023
(86) PCT No.: PCT/US2023/073154

§ 371 Date: Dec. 17, 2024

Related U.S. Application Data
(60) Provisional application No. 63/407,509, filed on Sep. 16, 2022.

(51) Int. Cl. H01S 3/08; G03F 7/20; H01S 3/1055

(52) U.S. Cl. CPC H01S 3/08004; G03F 7/2004; G03F 7/2008; H01S 3/08009; H01S 3/1055

(57) ABSTRACT

A deep ultraviolet laser system includes a line narrowing module including a plurality of prisms such that an incoming laser beam from a laser first interacts with a first prism, then interacts with a second prism after the first prism. The second prism includes two different portions including a first portion designed to work with and enable higher bandwidths of the incoming laser beam and a second portion designed to work with and enable lower bandwidths of the incoming laser beam. The second prism is movable between a first position in which the laser beam interacts with the first portion and a second position in which the laser beam interacts with the first portion. The second prism is movable by translation using an activation mechanism controlled by a controller to vary a target bandwidth of the laser beam.

### CROSS-REFERENCE TO RELATED APPLICATIONS

This application claims priority of U.S. application 63/407,509 which was filed on 16 Sep. 2022 and which is incorporated herein in its entirety by reference.

### TECHNICAL FIELD

The disclosed subject matter relates to an apparatus for controlling a spectral feature, such as, for example, bandwidth or wavelength, of a light beam output from an optical source that supplies light to a lithography exposure apparatus.

### BACKGROUND

In semiconductor lithography (or photolithography), the fabrication of an integrated circuit (IC) requires a variety of physical and chemical processes performed on a semiconductor (for example, silicon) substrate (which is also referred to as a wafer). A photolithography exposure apparatus or scanner is a machine that applies a desired pattern onto a target portion of the substrate. The wafer is fixed to a stage so that the wafer generally extends along a plane defined by orthogonal X_{L} and Y_{L} directions of the scanner. The wafer is irradiated by a light beam, which has a wavelength in the deep ultraviolet (DUV) range. The light beam travels along an axial direction, which corresponds with the Z_{L} direction of the scanner. The Z_{L} direction of the scanner is orthogonal to the lateral X_{L}-Y_{L} plane.

An accurate knowledge of spectral features or properties (for example, a wavelength and/or a bandwidth) of a light beam output from an optical source such as a laser is important in many scientific and industrial applications. For example, accurate knowledge of the optical source bandwidth is used to enable control of a minimum feature size or critical dimension (CD) in deep ultraviolet (DUV) optical lithography. The critical dimension is the feature size that is printed on a semiconductor substrate (also referred to as a wafer) and therefore the CD can require fine size control.

### SUMMARY

In some general aspects, a spectral feature control apparatus includes a spectral feature selection module including a plurality of prisms arranged in an optical plane and configured to receive and pass an incoming light beam along the optical plane. The plurality of prisms includes: a first prism positioned at an input side of the spectral feature selection module and configured to receive the incoming light beam; a second prism configured to receive the light beam that exits the first prism, the second prism including two or more portions, with each portion configured to enable a distinct bandwidth range of the light beam; and an activation mechanism configured to move the second prism along a direction relative to the optical plane to thereby select a bandwidth range of the light beam by positioning a specific portion of the second prism in the optical plane.

Implementations can include one or more of the following features. For example, the two or more portions can be stacked over one another with respect to the optical plane. The spectral feature selection module can be configured to select a wavelength of the light beam in the deep ultraviolet (DUV) range. The control apparatus can also include a first actuator configured to rotate the first prism. Rotation of the first prism can primarily modify an optical magnification of the light beam. The first actuator can be configured to rotate the first prism in a range of angles and the activation mechanism can be configured to move the second prism to thereby adjust the optical magnification of the light beam in a range of about 10× to about 50×. Adjustment of the optical magnification of the light beam in the range between about 10× and about 50× can primarily adjust the bandwidth of the light beam in the range between about 1000 femtometers (fm) and about 250 fm. The first actuator can include one or more of a motor, valve, pressure-controlled device, piezoelectric device, linear motor, hydraulic actuator, and voice coil.

The second prism can include a first portion stacked over a second portion, with the first portion, when positioned in the optical plane, configured to interact with a higher range of bandwidths of the light beam, and the second portion, when positioned in the optical plane, configured to interact with a lower range of bandwidths of the light beam. The first portion can have a first geometry and the second portion can have a second geometry that is different from the first geometry. The first portion being positioned in the optical path can enable the optical magnification of the light beam in the range between about 10× to about 19×, and the second portion being positioned in the optical path can enable the optical magnification of the light beam in the range between about 20× to about 50×. The first portion can include a first right-angled triangle geometry including one or more dimensions, and the second portion can include a second right-angled triangle geometry including one or more dimensions that are different from the first right-angled triangle geometry one or more dimensions. The first portion can include a wedge prism with at least one surface plane within the optical path, with the surface plane having a uniform and flat geometry. The control apparatus of claim 10, wherein the first portion comprises a wedge prism with at least one surface plane within the optical path, with the surface plane having a convex or concave geometry.

The activation mechanism being configured to move the second prism along a direction relative to the optical plane can include moving the second prism perpendicularly to the optical plane to select the bandwidth range of the light beam. The spectral feature selection module can also include a third prism and a fourth prism, and a diffractive optical element arranged to interact with the light beam in a Littrow configuration. Adjustment of the first and second prisms can primarily modify at least the optical magnification of the light beam to enable selection of the bandwidth of the light beam. The control apparatus can also include: a third actuator configured to rotate the third prism; and a fourth actuator configured to rotate the fourth prism. The rotation of the third and fourth prisms can primarily modify a central wavelength of the light beam. The third prism and the fourth prism each can include or be made of calcium fluoride or magnesium fluoride. The third prism and the fourth prism can each be right-angle triangle prisms.

The two or more portions of the second prism can include first and second portions, the first portion can include a material having a first refractive index and the second portion can include a material having a second refractive index that is different from the first refractive index. The two or more portions of the second prism can include first and second portions, the first portion can include a material having a first refractive index and the second portion can include a material having a second refractive index that is the same as the first refractive index. The first prism and the second prism each can include or be made of calcium fluoride or magnesium fluoride. The activation mechanism can include a pneumatic actuator or an electromechanical actuator.

In other general aspects, a method is described for controlling a wavelength and bandwidth of a light beam produced by an optical oscillator. The method includes: selecting a range of bandwidths from a set of distinct ranges of bandwidths including positioning a distinct portion of a second prism in an optical plane through which the light beam travels, the second prism including a plurality of distinct portions; controlling the optical magnification of the light beam produced from the optical oscillator to a desired optical magnification based on the selected range of bandwidths including directing the light beam through a first prism closest to the optical oscillator and through the distinct portion of the second prism positioned in the optical plane; adjusting an angle at which the light beam travels including directing the light beam through at least a third prism; and selecting the wavelength and bandwidth of the light beam based on the adjusted angle including impinging the light beam from the at least third prism on a dispersive optical element arranged to interact with the light beam in a Littrow configuration and selecting the wavelength and bandwidth of the light beam based on the optical magnification of the light beam impinging the dispersive optical element.

In other general aspects, a deep ultraviolet (DUV) laser system includes a line narrowing module including a plurality of prisms such that an incoming laser beam from a laser first interacts with a first prism, then interacts with a second prism after the first prism. The second prism includes two different stacked portions including a first portion designed to interact with higher bandwidths of the incoming laser beam and a second portion designed to interact with lower bandwidths of the incoming laser beam. The second prism is movable between a first position in which the laser beam interacts with the first portion and a second position in which the laser beam interacts with the first portion. The second prism is movable by translation using an activation mechanism controlled by a controller to vary a target bandwidth of the laser beam.

Implementations can include one or more of the following features. For example, the first portion can have a first shape and the second portion can have a second shape different than the first shape. The activation mechanism can be a pneumatic or electric activation mechanism.

In other general aspects, an illumination system includes: an optical source configured to produce a light beam; and a spectral feature control apparatus arranged to interact with the light beam produced by the optical source. The spectral feature control apparatus includes: a dispersive optical element; a beam expander including a plurality of prisms arranged in an optical path between the dispersive optical element and an aperture through which the light beam of the optical source can pass, the dispersive optical element and the beam expander being arranged such that the light beam of the optical source interacts with the aperture, the prisms, and the dispersive optical element along the optical path; and an activation mechanism configured to move a second prism of the beam expander along a direction that is not parallel with the optical path to select a bandwidth range of the light beam by positioning a specific geometrically-distinct portion of the second prism in the optical path. The second prism is positioned adjacent to a first prism that is closest to the aperture.

### DESCRIPTION OF DRAWINGS

FIG. 1 is a block diagram of a spectral feature control apparatus including a beam expander having a second prism that includes a first portion and a second portion;

FIG. 2A is a perspective view of an implementation of the second prism of FIG. 1;

FIG. 2B is an exploded perspective view of the second prism of FIG. 2A, showing details of the first portion and the second portion;

FIG. 2C is a top view of a spectral feature selection module including a beam expander that includes the second prism of FIGS. 2A and 2B, in which the plane of the page is the optical plane;

FIG. 2D is a side view of the second prism of FIGS. 2A-2C and an activation mechanism physically coupled to the second prism to move or translate the second prism such that the first portion is in the optical plane;

FIG. 2E is a side view of the second prism of FIGS. 2A-2C and an activation mechanism physically coupled to the second prism to move or translate the second prism such that the second portion is in the optical plane;

FIG. 3A is a top view of the spectral feature selection module of FIG. 2C in which the second prism is positioned such that the second portion is in the optical plane and a first prism is in a first extreme position to produce a light beam having a bandwidth based on an overall magnification determined at least in part by the position of the first prism and the position of the second portion in the optical plane;

FIG. 3B is a top view of the spectral feature selection module of FIG. 2C in which the second prism is positioned such that the second portion is in the optical plane and a first prism is in a second extreme position to produce a light beam having a bandwidth based on an overall magnification determined at least in part by the position of the first prism and the position of the second portion in the optical plane;

FIG. 4A is a top view of the spectral feature selection module of FIG. 2C in which the second prism is positioned such that the first portion is in the optical plane and a first prism is in a first extreme position to produce a light beam having a bandwidth based on an overall magnification determined at least in part by the position of the first prism and the position of the second portion in the optical plane;

FIG. 4B is a top view of the spectral feature selection module of FIG. 2C in which the second prism is positioned such that the first portion is in the optical plane and a first prism is in a second extreme position to produce a light beam having a bandwidth based on an overall magnification determined at least in part by the position of the first prism and the position of the second portion in the optical plane;

FIG. 5A is a perspective view of another implementation of the second prism of FIG. 1;

FIG. 5B is an exploded perspective view of the second prism of FIG. 5A, showing details of the first portion and the second portion;

FIG. 6A is a perspective view of another implementation of the second prism of FIG. 1;

FIG. 6B is an exploded perspective view of the second prism of FIG. 6A, showing details of the first portion and the second portion;

FIG. 7A is a perspective view of another implementation of the second prism of FIG. 1;

FIG. 7B is an exploded perspective view of the second prism of FIG. 7A, showing details of the first portion and the second portion;

FIG. 8A is a perspective view of another implementation of the second prism of FIG. 1;

FIG. 8B is an exploded perspective view of the second prism of FIG. 8A, showing details of the first portion and the second portion;

FIG. 9 is a block diagram of a photolithography system including an illumination system that produces a pulsed light beam directed to a photolithography exposure apparatus, the pulsed light beam being formed from a light beam produced by the optical source of FIG. 1; and

FIG. 10 is a graph depicting an optical spectrum of the light beam produced from the illumination system of FIG. 9, the optical spectrum defined by a center wavelength and a bandwidth of the light beam.

### DESCRIPTION

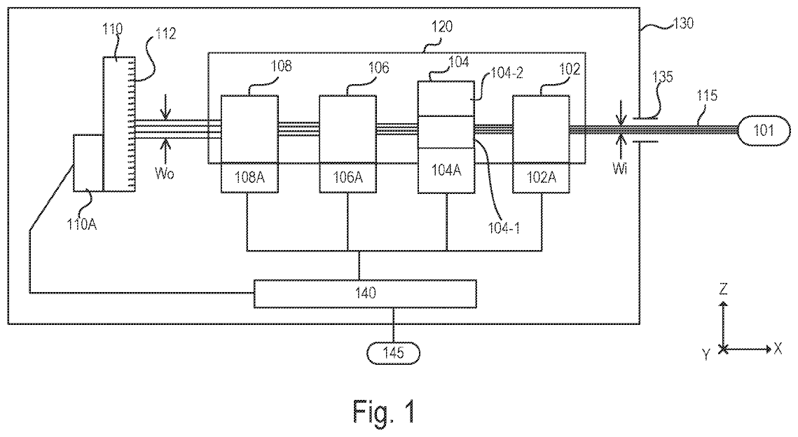

Referring to FIG. 1, a spectral feature control apparatus 100 includes a spectral feature selection module 130 configured to receive, through an aperture 135, a light beam 115 produced by an optical source 101. The spectral feature selection module 130 includes optical features or components 102, 104, 106, 108, 110 that can be arranged in a Littrow configuration. The optical components 102, 104, 106, 108, 110 are configured to interact with the light beam 115 received within the spectral feature selection module 130. The optical components 102, 104, 106, 108, 110 can further be configured to modify and adjust spectral properties (such as bandwidth or wavelength) of the light beam 115. The light beam 115 can have wavelengths that are within the deep ultraviolet (DUV) range. The light beam 115 can be a pulsed light beam, as discussed in more detail below, that is used for patterning microelectronic features on a substrate (or wafer) received in a photolithography exposure apparatus.

The spectral feature selection module 130 can be configured with a beam expander 120 that is made up of the optical components 102, 104, 106, 108. The optical components 102, 104, 106, 108 can be configured as transmissive and refractive optical elements such as optical prisms. In particular, the optical components 102, 104, 106, 108 can be configured and respectively implemented as a first prism 102, a second prism 104, a third prism 106, and a fourth prism 108. Each prism 102, 104, 106, 108 is configured to refract and redirect the light beam 115 as it passes through the body of the prism 102, 104, 106, 108. The light beam 115 is optically expanded by the beam expander 120 as it travels from the aperture 135 toward the grating 110 and is optically compressed by the beam expander 120 as it travels from the grating 110 toward the aperture 135.

The optical components 102, 104, 106, 108 are made of a material or materials that permit the

transmission of the wavelength of the light beam 115. For example, the optical components 102, 104, 106, 108 can be made of materials such as calcium fluoride or magnesium fluoride that are compatible with the DUV wavelengths of the light beam 115, and also allow the optical components 102, 104, 106, 108 to be implemented as transmissive prisms. When the optical components 102, 104, 106, 108 are transmissive prisms, the optical components 102, 104, 106, 108 act to disperse, deviate, and redirect the light beam 115 as it passes through the body of the respective prism. Moreover, the spectral feature selection module 130 can also be configured with a diffractive optical element 110 that can be, for example, an optical grating with a diffractive surface 112. The grating 110 is designed to disperse, diffract, and reflect the light beam 115. The grating 110 and the diffractive surface 112 of the grating 110 are made of material that is compatible with the wavelength of the light beam 115 and acts to reflect and diffract the light beam 115 that comes in contact with the diffractive surface 112. For example, the grating 110 (and the surface 112) can be made of calcium fluoride or magnesium fluoride.

As shown in FIG. 1, within the beam expander 120, the optical components 102, 104, 106, 108, 110 can be consecutively arranged such that an optical plane is defined. The light beam 115 propagates through and within the optical plane when received within the spectral feature control apparatus 100. In this example, the optical plane is generally the XY plane. In particular, within the spectral feature selection module 130, the first prism 102 can be positioned closest to the aperture 135 followed by the second prism 104, the third prism 105, and the fourth prism 108, with the fourth prism 108 being positioned farthest from the aperture 135. Therefore, when the light beam 115 is received within the spectral feature selection module 130 by way of the aperture 135, the light beam 115 is initially received by the beam expander 120, and specifically at the first prism 102 before passing consecutively through the second prism 104, the third prism 105, and the fourth prism 108.

The light beam 115 that exits the beam expander 120 through the fourth prism 108 is directed to the grating 110. The diffractive surface 112 of the grating 110 causes the light beam 115 to be diffracted and reflected back through the beam expander 120 and to the aperture 135 in the reverse order that the light beam 115 was received. In particular, the light beam 115 that is reflected from the diffractive surface 112 is received by the fourth prism 108, followed by the third prism 104, the second prism 104, and finally the first prism 102, which directs the light beam 115 out of the spectral feature selection module 130 by way of the aperture 135. As the light beam 115 travels from the grating 110 through the spectral feature selection module 130 in this reverse manner, the light beam 115 is optically compressed by each of the optical components 108, 106, 104, 102.

Initially, as mentioned, when the light beam 115 enters the spectral feature selection module 130 by way of the aperture 135, the light beam 115 is directed toward beam expander 120 and is received by the first prism 102 arranged within the beam expander 120. The first prism 102 can be configured to be rotated within the optical plane to thereby modify or adjust one or more spectral properties of the light beam 115. Specifically, rotation of the first prism 102 in the optical plane primarily adjusts an optical magnification of the light beam 115 at the grating 110. The optical magnification of the light beam 115 is the ratio of a transverse width Wo of the light beam 115 exiting the beam expander 120 (on the path to the grating 110) to a transverse width Wi of the light beam 115 entering the beam expander 120 (from the optical source 101). Adjustment of the optical magnification of the light beam 115 at the grating 110 causes an adjustment to a bandwidth of the light beam 115. The third prism 106 and the fourth prism 108 can each be configured to be rotated within the optical plane to thereby modify or adjust one or more spectral properties of the light beam 115. Specifically, rotation of the third prism 106 and the fourth prism 108 primarily adjusts an angle of incidence of the light beam 115 at the grating 110. Adjustment of the angle of incidence of the light beam 115 at the grating 110 causes an adjustment to a wavelength of the light beam 115.

Because the adjustment to the bandwidth of the light beam 115 primarily relies on the rotation of the first prism 102, in prior spectral feature control apparatuses, the range of bandwidths that can be achieved by such prior spectral feature control apparatuses is limited by the rotation of the first prism 102 and also by the geometry of the first prism 102. This is because the rotation of the first prism 102 primarily adjusts the optical magnification of the light beam 115 at the grating 110 within a particular limited range. For example, in some implementations, rotation of the first prism 102 enables a range of optical magnification of the light beam 115 at the grating 110 of about 19× to about 50×. And, this range of optical magnification corresponds to a range of bandwidths of about 200 femtometers (fm) to about 500 fm, respectively. Thus, in this example, if a bandwidth of 300 fm is desired initially, then the prior spectral feature control apparatus would be unable to adjust the first prism 102 to obtain a bandwidth of 800 fm.

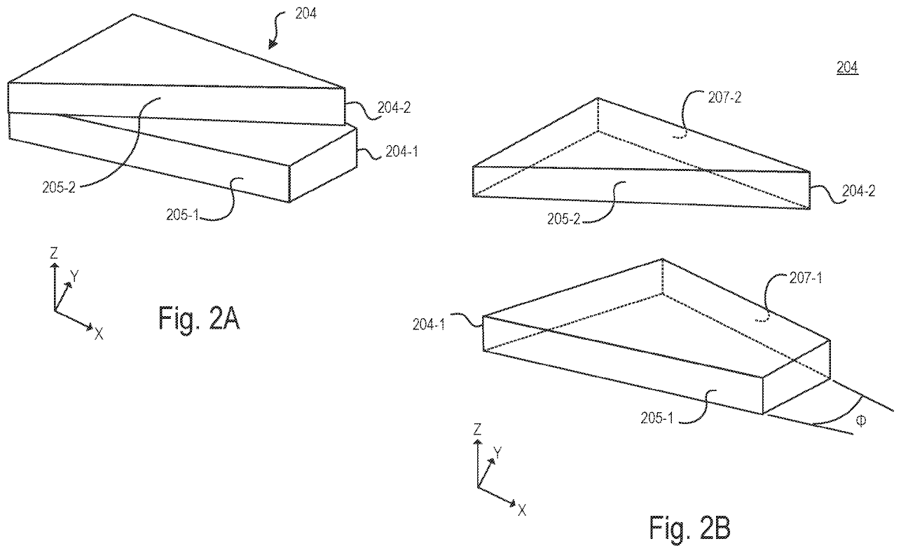

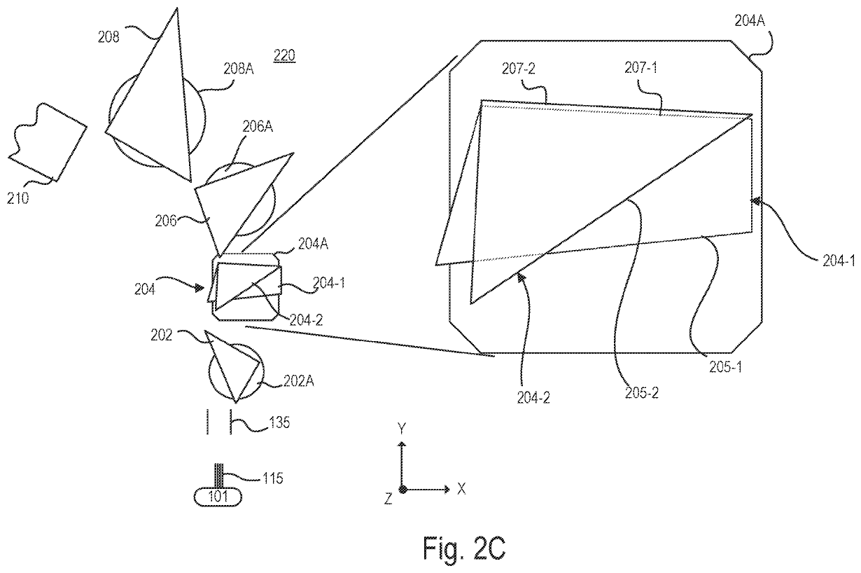

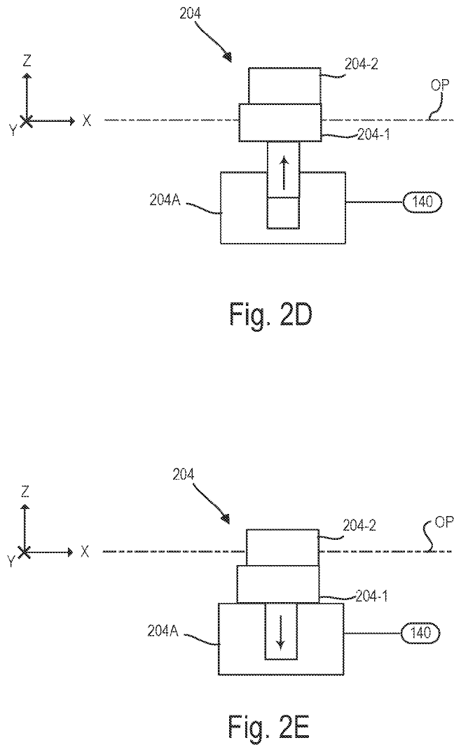

The spectral feature control apparatus 100 is designed to enable adjustment of the bandwidth of the light beam 115 in a larger range than is possible in the prior apparatus by converting the second prism 104 into a multi-portion second prism 104. Specifically, the second prism 104 includes a first portion 104-1 and a second portion 104-2 that can be stacked along the Z direction relative to the first portion 104-1. When the first portion 104-1 is in the optical plane XY (as is shown in the configuration of FIG. 1 and also shown in FIG. 2D with respect to a first portion 204-1 of a second prism 204), the first portion 104-1 is designed and configured to interact with the light beam 115 and thereby work in a first bandwidth range. When the first portion 104-1 is in the optical plane XY, the second portion 104-2 is not in the optical plane and is not interacting with the light beam 115, as shown in FIG. 1. When the second portion 104-2 is in the optical plane XY (as shown in FIG. 2E with respect to a second portion 204-2 of the second prism 204), the second portion 104-2 is designed and configured to interact with the light beam 115 and thereby work in a second bandwidth range that is distinct from the first bandwidth range. When the second portion 104-2 is in the optical plane XY, the first portion 104-1 is not in the optical plane and is not interacting with the light beam 115. For example, the first portion 104-1 can be configured to receive and interact with a higher range of bandwidths of the light beam 115, and the second portion 104-2 can be configured to receive and interact with a lower range of bandwidths of the light beam 115. By breaking or separating the second prism 104 into these differently-designed portions 104-1 and 104-2, and selecting a first portion for a first range of bandwidths and a second portion for a second range of bandwidths, the spectral feature control apparatus 100 operates in a wider range of bandwidths without requiring modification of the apparatus 100 or changing components within the apparatus 100 during operation of the optical source 101.

Moreover, the expanded range of bandwidths enables a reduction in an edge placement error (EPE) that can occur at the substrate that receives the light beam 115. Specifically, edge placement errors at the features patterned on the substrate with the light beam 115 can occur. Edge placement error is the difference between the intended and the printed features of the layout at the substrate. In particular, the light beam 115 needs to pattern tiny features in precise locations on the substrate. For example, a feature could be a line, and that line has right and left edges. If the line and its right and/or left edges are not precise in shape and form or placed in the correct location, misalignment (or EPE) can occur. And if one or more EPE issues crop up in the production flow of the substrate, the device made with the substrate that includes all of these EPE issues is subject to electrical shorts or poor yields, which could cause the entire chip formed on the substrate to fail. In order to reduce the EPE issues, higher bandwidths in the light beam 115 are needed. The spectral feature control apparatus 100 enables these higher bandwidths in the light beam 115 by using the second prism 104, which includes the two differently-designed portions 104-1 and 104-2. In some implementations, the geometry and shape of the second portion 104-2 is different

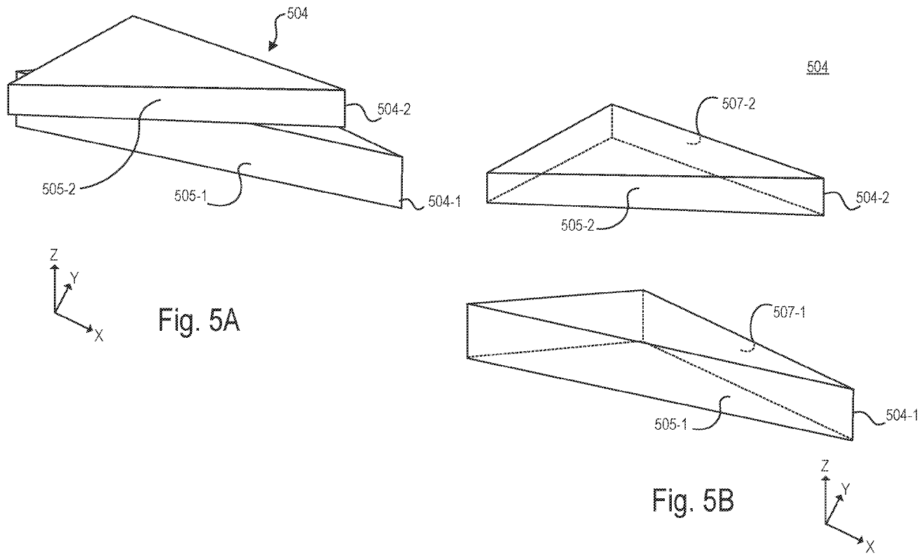

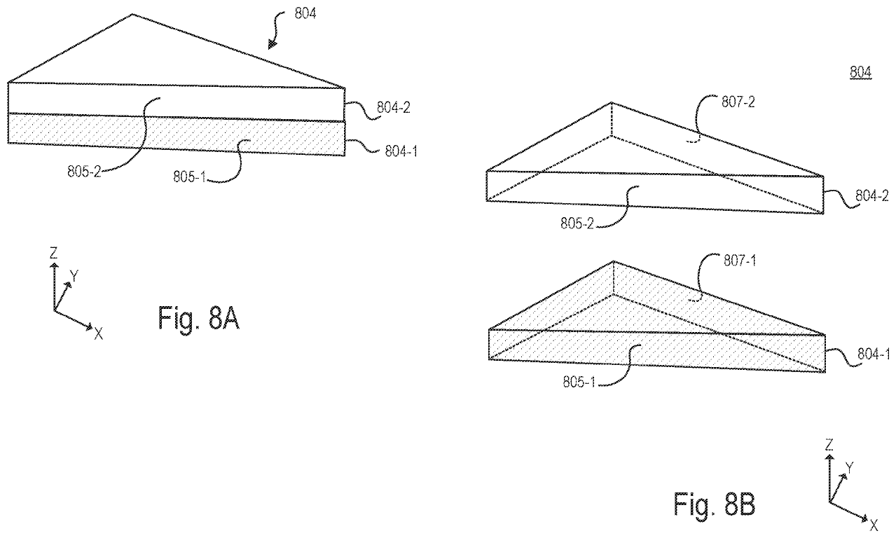

from the geometry and shape of the first portion 104-1. Examples of the possible different geometries and shapes are discussed below with reference to FIGS. 2A and 2B, 3A and 3B, 4A and 4B, and 7A and 7B. In some implementations, the material of the second portion 104-2 is different from the material of the first portion 104-1, as discussed with reference to FIGS. 8A and 8B. In some implementations, as discussed with reference to FIGS. 5A and 5B, the scale and placement of the second portion 104-2 can be different from the scale and placement of the first portion 104-1.

As further shown in FIG. 1, the spectral feature selection module 130 optical components 102, 104, 106, 108, 110 can be configured with and mechanically coupled to respective actuation systems 102A, 104A, 106A, 108A, 110A. The actuation systems 102A, 104A, 106A, 108A, 110A can be configured to move the respective optical components 102, 104, 106, 108, 110 to adjust one or more spectral properties of the light beam 115. In general, each of the actuation systems 102A, 104A, 106A, 108A, 110A is a mechanical device for moving or controlling the respective optical component. The actuation systems 102A, 104A, 106A, 108A, 110A can receive energy from a control module 140, and can convert the energy into some kind of motion imparted to the respective optical component. For example, the actuation systems 102A, 106A, 108A, 110A can be or include any one of force devices and rotation stages for rotating one or more of the prisms or the grating 110. The actuation systems 102A, 106A, 108A, 110A can include, for example, motors such as stepper motors, valves, pressure-controlled devices, piezoelectric devices, linear motors, hydraulic actuators, voice coils, etc. Although an actuation system 110A is shown relative to the grating 110, it is alternatively possible for the grating 110 to be fixed in various orientations. Similarly, it is alternatively possible for either of the prisms 106 and 108 to be fixed while the other is movable (rotatable) in the optical plane.

The actuation system 104A mechanically coupled to the second prism 104 can be configured as a activation mechanism that can be or include, for example, a pneumatic actuator or an electromechanical actuator. The activation mechanism 104A can be configured to translate the first portion 104-1 and the second portion 104-2 of the second prism 104 along the Z direction perpendicular to the XY plane of the optical plane, and thereby allow the first portion 104-1 and the second portion 104-2 to be moved into and out of the optical plane (the XY plane). Because the first portion 104-1 and the second portion 104-2 are configured to select and operate in different bandwidth ranges, the activation mechanism 104A permits different bandwidth ranges to be selected.

The control module 140 can include electronics in the form of any combination of hardware, firmware, and software. The control module 140 can be configured to provide energy or electrical power to the actuation systems 102A, 104A, 106A, 108A, 110A, and control and monitor the movement of the respective optical components 102, 104, 106, 108, 110 to which the actuation systems are mechanically coupled to. Moreover, the control module 140 can also be configured receive control signals from a control system 145. The control system 145 can also be configured to communicate with the optical source 101. The control system 145 can be configured to send control signals to the control module 140 that can include, for example, specific commands to operate or control one or more of the actuations systems 102A, 104A, 106A, 108A, 110A, and thereby determine the position of the optical components 102, 104, 106, 108, 110.

Referring to FIGS. 2A-2C, an implementation 204 of the second prism 104 is shown. In FIG. 2A, the second prism 204 is shown in a perspective view separated from the beam expander 120, and in FIG. 2B, the second prism 204 is shown in an exploded perspective view (with transparency to show all of the surfaces) and separated from the beam expander. In FIG. 2C, the second prism 204 is shown arranged within an implementation 220 of the beam expander 120. The second prism 204 includes a second portion 204-2 stacked on a first portion 204-1.

In this implementation, the second portion 204-2 has a triangle geometry and the first portion 204-1 has a wedge geometry. The second portion 204-2 can be a triangle-shaped prism and in some implementations, the triangle can be a right-angle triangle. The first portion 204-1 can be a wedge prism that has a wedge angle Φ in the range of 0° to 45° (FIG. 2B).

The beam expander 220 also includes a first prism 202 as the first optical component 102, a third prism 206 as the third optical component 106, a fourth prism 208 as the fourth optical component 108, and a grating 210 arranged to interact with the light beam 115 that passes through the beam expander 220. The prisms 202, 204, 206, 208 generally increase in the size of the surface area interacting with the light beam 115 from the first prism 202 closest to the aperture 135 to the fourth prism 208 farthest from the aperture 135.

The first portion 204-1 includes a front surface 205-1 facing the first prism 202 and a back surface 207-1 (FIG. 2B) facing the third prism 206 when the first portion 204-1 is positioned in the optical plane (the XY plane). While the surface 205-1 is referred to as “front” it should be noted that this term refers to its position relative to the first prism 202 and similarly while the surface 207-1 is referred to as “back” it should be noted that this term refers to its position relative to the third prism 206. When the first portion 204-1 is in the optical plane (the XY plane), the light beam 115 enters the front surface 205-1 as it exits the first prism 202 and it exits the back surface 207-1 as it travels toward the third prism 206. On the return path (from the grating 210), the light beam 115 enters the back surface 207-1 as it exits the third prism 206 and it exits the front surface 205-1 as it travels toward the first prism 202.

The second portion 204-2 includes a front surface 205-2 facing the first prism 202 and a back surface 207-2 (FIG. 2B) facing the third prism 206 when the second portion 204-2 is positioned in the optical plane (the XY plane). While the surface 205-2 is referred to as “front” it should be noted that this term refers to its position relative to the first prism 202 and similarly while the surface 207-2 is referred to as “back” it should be noted that this term refers to its position relative to the third prism 206. When the second portion 204-2 is in the optical plane (the XY plane), the light beam 115 enters the front surface 205-2 as it exits the first prism 202 and it exits the back surface 207-2 as it travels toward the third prism 206. On the return path (from the grating 210), the light beam 115 enters the back surface 207-2 as it exits the third prism 206 and it exits the front surface 205-2 as it travels toward the first prism 202.

As discussed above with reference to FIG. 1, the second prism 104 is physically coupled to an activation mechanism 104A. An implementation 204A of the activation mechanism 104A is shown in FIG. 2C. Operation of the activation mechanism 204A is shown in FIGS. 2D and 2E. The activation mechanism 204A can be any suitable mechanism configured to move the prism 204 along the Z direction such that the first portion 204-1 and the second portion 204-2 are alternatingly placed in the optical plane (the XY plane), which is also labeled as OP in FIGS. 2D and 2E. The activation mechanism 204A can be a device that includes a linear motor, a pressure-controlled device, a piezoelectric device, a hydraulic or pneumatic actuator, or an electromagnetic actuator. As shown in FIG. 2D, upon receiving an instruction from the control module 140 to position the first portion 204-1 of the prism 204 in the optical plane OP, the activation mechanism 204A translates the prism 204 along the +Z direction so that the first portion 204-1 of the prism 204 is positioned in the optical plane OP. As shown in FIG. 2E, upon receiving an instruction from the control module 140 to position the second portion 204-2 of the prism 204 in the optical plane OP, the activation mechanism 204A translates the prism 204 along the −Z direction so that the second portion 204-2 of the prism 204 is positioned in the optical plane OP.

Referring again to FIG. 2C, an implementation 202A of the first actuator 102A is configured to rotate the first prism 202 in the optical plane (the XY plane) and about an actuation axis that is parallel with the Z direction; the actuation axis can correspond to an axis of the first prism 202 or it can be parallel with the axis of the first prism 202. Generally, the first actuator 102A is configured to rotate the first prism 202 within a range of angles from 0 to about 20°. Additionally, an implementation 206A of the third actuator 106A is configured to rotate the third prism 206 in the optical plane (the XY plane) and about an actuation axis (such as the axis of the third prism 206) that is parallel with the Z direction. Lastly, an implementation 208A of the fourth actuator 108A is configured to rotate the fourth prism 208 in the optical plane (the XY plane) and about an actuation axis (such as the axis of the fourth prism 208) that is parallel with the Z direction. Each actuation system 202A, 206A, 208A can be or can include any one of a force device and rotation stage for rotating its associated prism 202, 206, 208. Each actuation system 202A, 206A, 208A can include, for example, a motor such as a stepper motor, one or more valves, a pressure-controlled device, a piezoelectric device, a linear motor, a hydraulic actuator, a voice coil, etc.

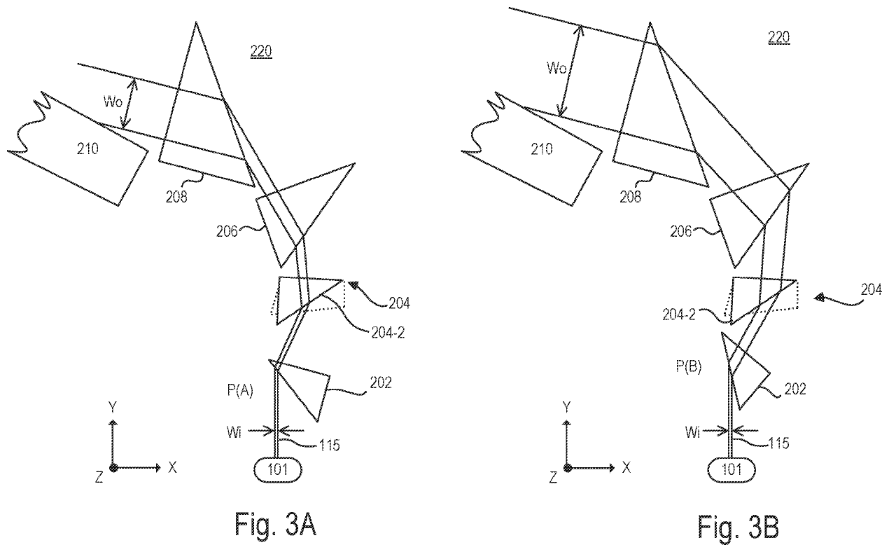

Referring to FIGS. 3A and 3B, the second prism 204 is positioned such that the second portion 204-2 is in the optical plane (the XY plane), such as shown in FIG. 2E. In this example, the first prism 202 is rotated between a first position P(A) as shown in FIG. 3A and a second position P(B) as shown in FIG. 3B. The second position P(B) is obtained by rotating the first prism 202 about an actuation axis that, in this particular example, is not aligned with the center of gravity (that defines the prism axis) of the prism 202 and thus there is some rotation as well as some translation of the prism 202. This change in position to the first prism 202 causes the light beam 115 to impinge upon the front surface of the first prism 202 at a different angle and location in the arrangement of FIG. 3B relative to the arrangement of FIG. 3A. This change in the location of impingement upon the front surface of the first prism 202 causes a cascading change in the path or direction of the light beam 115 directed to each of the second prism 204, the third prism 206, and the fourth prism 208 as well as a cascading change in the optical magnification at each of the second prism 204, the third prism 206, and the fourth prism 208 such that by the time the light beam 115 reaches the grating 210, the light beam 115 is approaching the grating 210 at a different angle and at a different transverse extent Wo in the arrangement of FIG. 3B relative to the arrangement of FIG. 3A.

In particular, when the first prism 202 in the position P(A), as shown in FIG. 3A, the overall optical magnification at the grating 210 is 20×. That is, the ratio of the width Wo to the width Wi is 20. This optical magnification is due to the placement of the first prism 202 in the first position P(A) as well as the placement of the second portion 204-2 of the second prism 204 in the optical plane. On the other hand, when the first prism 202 is in the position P(B), as shown in FIG. 3B, the overall optical magnification at the grating 210 is 50×. That is, the ratio of the width Wo to the width Wi is 50. This optical magnification is due to the placement of the first prism 202 in the first position P(B) as well as the placement of the second portion 204-2 of the second prism 204 in the optical plane.

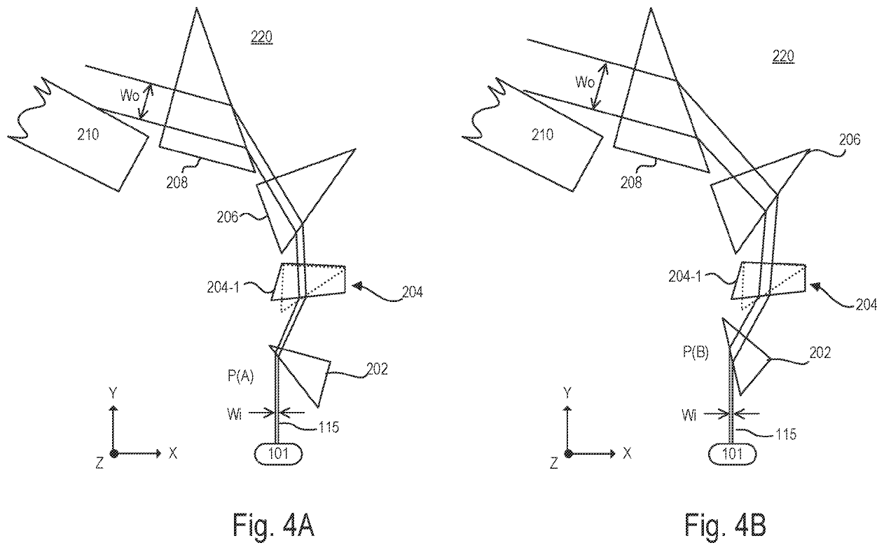

Referring to FIGS. 4A and 4B, the second prism 204 is positioned such that the first portion 204-1 is in the optical plane (the XY plane), such as shown in FIG. 2D. The first prism 202 can be rotated between the first position P(A) as shown in FIG. 4A and the second position P(B) as shown in FIG. 4B. When the first prism 202 is in the position P(A), as shown in FIG. 4A, the overall optical magnification at the grating 210 is 10×. That is, the ratio of the width Wo to the width Wi is 10. This optical magnification is due to the placement of the first prism 202 in the first position P(A) as well as the placement of the first portion 204-1 of the second prism 204 in the optical plane. On the other hand, when the first prism 202 is in the second position P(B), as shown in FIG. 4B, the overall optical magnification at the grating 210 is 19×. That is, the ratio of the width Wo to the width Wi is 19. This optical magnification is due to the placement of the first prism 202 in the first position P(B) as well as the placement of the first portion 204-1 of the second prism 204 in the optical plane.

Accordingly, adjustments to the overall optical magnification are affected by the first actuator 202A adjusting the position of the first prism 202 in the optical plane and by the activation mechanism 204A adjusting the position of the second prism 204 in the Z direction perpendicular to the optical plane, and under control of the control module 140. At the optical magnification of 20× (FIG. 3A), the light beam 115 can have a bandwidth of about 480 fm. At the optical magnification of 50× (FIG. 3B), the light beam 115 can have a bandwidth of about 250 fm. At the optical magnification of 10× (FIG. 4A), the light beam 115 can have a bandwidth of about 1000 fm. At the optical magnification of 19× (FIG. 4B), the light beam 115 can have a bandwidth of about 520 fm. The actual value of the bandwidth can be fine-tuned around a particular bandwidth value by tens of fin from an initial bandwidth of the incoming light beam 115 by controlling an initial incoming condition of the light beam 115, such that there can be an overlap for any bandwidth value and any target value within about 250-1000 fm can be achieved by the spectral feature control apparatus 100. In this way, the beam expander 220 (which can be implemented in the spectral feature control apparatus 100) enables the selection of two different bandwidth ranges (from about 250-500 fm or from about 500-1000 fm) and a selection of a much wider range of bandwidths in general.

The change in the optical magnification in the two different configurations (FIGS. 3A/3B versus FIGS. 4A/4B) is due to the different geometries of the first portion 204-1 and the second portion 204-2. Unlike the second portion 204-2, which is a right-angled prism, the first portion 204-1 is a wedge-shaped prism that includes two extending surface planes, that is, the front surface 205-1 and the back surface 207-1. These two surface planes are positioned at an angle (the wedge angle Φ) relative to each other that is different from the angle at which the front surface 205-2 and the back surface 207-2 of the second portion 204-2 are positioned. This is shown more clearly in FIG. 2B. Because the first portion 204-1 has a different geometry than the geometry of the second portion 204-2, the first portion 204-1 modifies the optical properties of the light beam 115 that is passed through first portion 204-1 differently than that of the second portion 204-2 and this permits different selectable bandwidth ranges that are not able to be achieved only through the orientation of the first prism 202 within the optical plane OP with a single portion second prism (in prior designs). In particular, when comparing the arrangement of FIG. 4B to the arrangement of FIG. 3B, it is evident that the light beam 115 impinges upon the front surface 205-1 (see FIG. 2A) of the first portion 204-1 in FIG. 4B in a manner that is different from how the light beam 115 impinges upon the first surface 205-2 (see FIG. 2A) of the second portion 204-2 in FIG. 3B. Specifically, the light beam 115 experiences a different angle and location at which it enters the second prism 204 in these two arrangements. Additionally, the light beam 115 also experiences a different angle and location at which it exits the second prism 204 in these two arrangements. Because of this, there is an additional cascading change in the optical magnification of the light beam 115 as it travels through the third prism 206 and the fourth prism 208 and this shows up as an overall change in the optical magnification of the light beam 115 at the grating 210 in the arrangement of FIG. 4B relative to the arrangement of FIG. 3B.

Other implementations of the second prism 104 are possible. For example, as shown in FIGS. 5A and 5B, an implementation 504 of the second prism 104 includes a first portion 504-1 that is a first triangle-shaped prism and a second portion 504-2 that is a second triangle-shaped prism that has a different shape/scale from the first triangle-shaped prism. Additionally, the second triangle-shaped prism 504-2 is oriented at a different angle from the first triangle-shaped prism 504-1 such that the front surface 505-2 of the second triangle-shaped prism 504-2 is at a different angle from the front surface 505-1 of the first triangle-shaped prism 504-1.

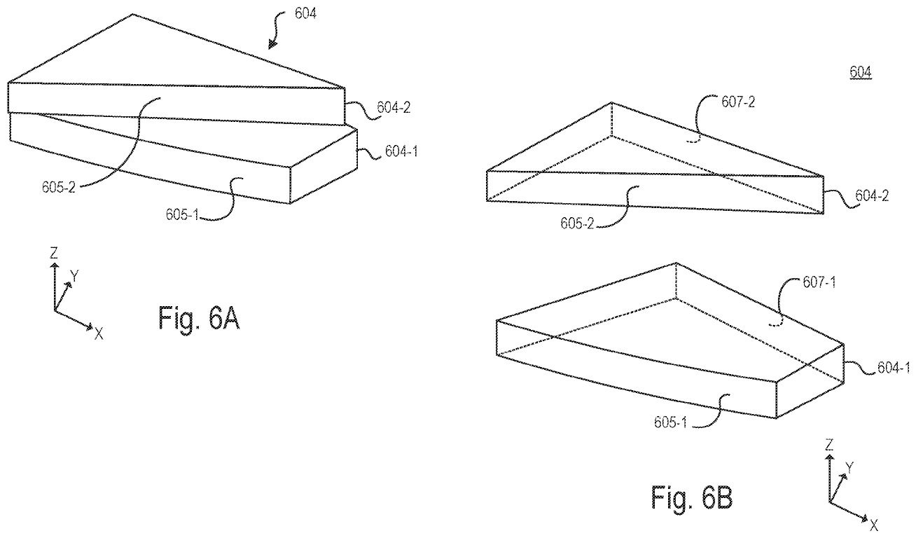

As shown in FIGS. 2A and 2B, the front surface 205-1 of the wedge prism (the first portion) 204-1 is planar. In other implementations, as shown in FIGS. 6A and 6B, a front surface 605-1 of the wedge prism (the first portion) 604-1 is convex. Specifically, an implementation 604 of the second prism 104 includes a wedge prism as the first portion 604-1 and a triangle-shaped prism as the second portion 604-2, where the triangle-shaped prism 604-2 can be a right-angled triangle prism. The wedge prism 604-1 includes the front surface 605-1, which is convex, and a back surface 607-1. When the wedge prism 604-1 is positioned in the optical plane, the light beam 115 from the aperture 135 first enters the front surface 605-1 and then exits the back surface 607-1. The convex surface (the front surface) 605-1 of the wedge prism 604-1 acts to converge the light beam 115 and also enables additional flexibility to control the magnification and the size or transverse extent of the light beam 115 as it interacts with the grating 210. The triangle-shaped prism 604-2 includes a front surface 605-2 and a back surface 607-2. When the triangle-shaped prism 604-2 is positioned in the optical plane, the light beam 115 from the aperture 135 first enters the front surface 605-2 and then exits the back surface 607-2.

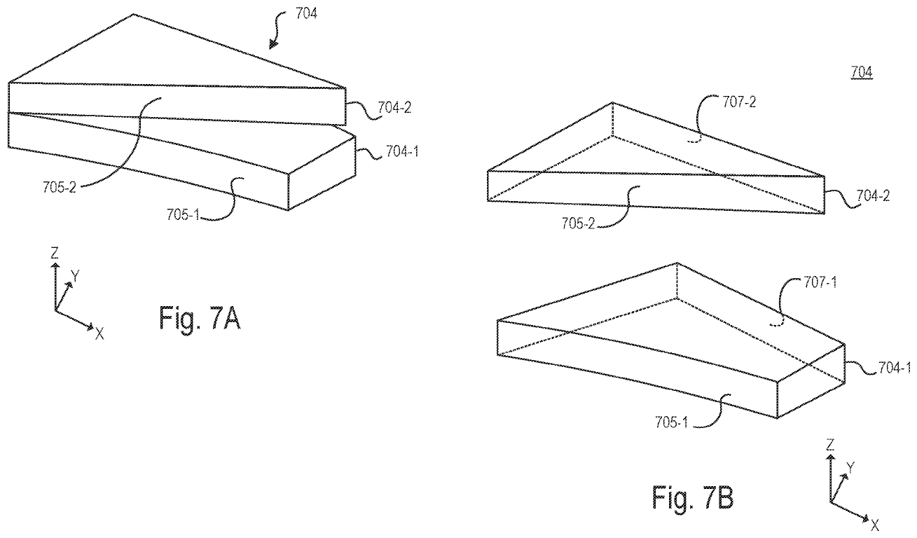

In other implementations, as shown in FIGS. 7A and 7B, a front surface 705-1 of the wedge prism (the first portion) 704-1 is concave. Specifically, an implementation 704 of the second prism 104 includes a wedge prism as the first portion 704-1 and a triangle-shaped prism as the second portion 704-2, where the triangle-shaped prism 704-2 can be a right-angled triangle prism. The wedge prism 704-1 includes the front surface 705-1, which is concave, and a back surface 707-1. When the wedge prism 704-1 is positioned in the optical plane (such as shown in FIGS. 4A and 4B), the light beam 115 from the aperture 135 first enters the front surface 705-1 and then exits the back surface 707-1. The concave surface (the front surface) 705-1 of the wedge prism 704-1 acts to diverge the light beam 115 and also enables additional flexibility to control the magnification and the size or transverse extent of the light beam 115 as it interacts with the grating 210. The triangle-shaped prism 704-2 includes a front surface 705-2 and a back surface 707-2. When the triangle-shaped prism 704-2 is positioned in the optical plane (such as shown in FIGS. 3A and 3B), the light beam 115 from the aperture 135 first enters the front surface 705-2 and then exits the back surface 707-2.

Referring to FIGS. 8A and 8B, another implementation 804 of the second prism 104 is shown. The second prism 804 includes a first portion 804-1 and a second portion 804-2 stacked on the first portion. The shape of the first portion 804-1 can be the same as the shape of the first portion 804-2, but the material used in the second portion 804-2 is distinct from the material used in the first portion 804-1. In this way, the light beam 115 behaves differently in each of the first portion 804-1 and the second portion 804-2. While using distinct materials in the second portion 804-2 and the first portion 804-1 can enable an increase in the bandwidth range by a small amount when using the same shapes, it is also possible to use distinct materials in the second portions 204-2/504-2/604-2/704-2 relative to the respective first portions 204-1/504-1/604-1/704-1 to obtain a larger bandwidth range for those beam expanders.

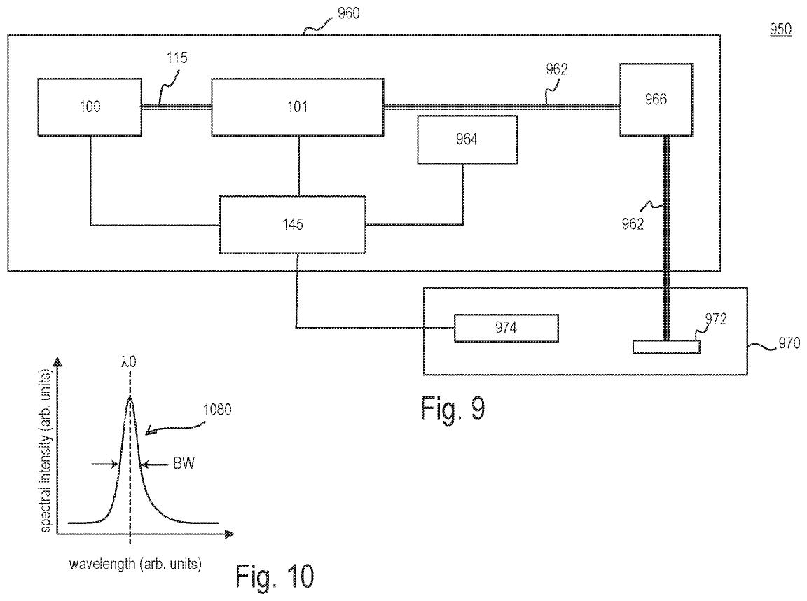

Referring to FIG. 9, the spectral feature control apparatus 100 is implemented in a photolithography system 950. The photolithography system 950 includes an illumination system 960 that produces a pulsed light beam 962 having a wavelength that is nominally at a center wavelength (as determined by the angle of incidence of the light beam 115 at the grating 110 in FIG. 1). The pulsed light beam 962 is directed to the photolithography exposure apparatus 970. The pulsed light beam 962 is formed from the light beam 115 produced by the optical source 101. The pulsed light beam 962 is used to pattern microelectronic features on a substrate 972 received in the apparatus 970. The illumination system 960 includes the optical source 101, which produces the pulsed light beam 962 at a pulse repetition rate that is desired by the apparatus 970. The illumination system 960 includes the control system 145 that communicates with the optical source 101, the spectral feature control apparatus 100, and other features within the illumination system 960, including a metrology system 964. The control system 145 also communicates with the photolithography exposure apparatus 970 by way of a lithography controller 974. The light beam 962 is directed through a beam preparation system 966, which can include optical elements, such as reflective or refractive optical elements, optical pulse stretchers, or optical apertures or shutters, that modify aspects of the light beam 962.

The pulses of the light beam 962 are centered around a wavelength (which is determined by the angle of incidence of the light beam 115 at the grating 110 in FIG. 1) and the center wavelength is in the deep ultraviolet (DUV) range, which can include wavelengths from, for example, about 100 nanometers (nm) to about 400 nm. The size of the microelectronic features patterned on the substrate 972 depends on the center wavelength of the light beam 962, with a lower center wavelength resulting in a smaller minimum feature size or critical dimension. When the wavelength of the light beam 962 is 248 nm or 193 nm, the minimum feature size can be, for example, 50 nm or less. The bandwidth of the light beam 962 can be the actual, instantaneous bandwidth of the optical spectrum of the light beam 962. A depiction 1080 of the optical spectrum of the light beam 962 is shown in FIG. 10, with a depiction of the bandwidth BW and the center wavelength λ0. The optical spectrum 1080 contains information about how the optical energy or power of the light beam 962 is distributed over different wavelengths or frequencies.

The spectral feature control apparatus 100 is placed at a first end of the optical source 101 to interact with the light beam 115. The light beam 115 is a light beam produced at one end of a resonator within the optical source 101. In some implementations, the optical source 101 can be a dual-stage optical source that includes a first stage having a master oscillator and a second stage having a power amplifier. The master oscillator (MO) produces a first light beam, which is passed to the power amplifier by way of optical elements that includes relay optics. The power amplifier (PA) receives the first light beam and optically amplifies the first light beam to form the output light beam 962. In such a configuration of the optical source 101, the spectral feature control apparatus 100 can be arranged to receive the first light beam of the master oscillator. The master oscillator (MO) typically includes a gain medium in which amplification occurs and an optical feedback mechanism such as an optical resonator. The power amplifier (PA) typically includes a gain medium in which amplification occurs when seeded with the first light beam from the master oscillator. The spectral feature control apparatus 100 receives the light beam 115, which is from the master oscillator, to enable fine turning of spectral features such as the center wavelength and the bandwidth of the light beam 115 at relative low output pulse energies. The power amplifier amplifies the output (the first light beam) from the master oscillator to attain the necessary power in the light beam 962 for use by the photolithography exposure apparatus 970. An example of such an optical source 101 is described and discussed in U.S. Pat. No. 10,416,471, “Spectral Feature Control Apparatus,” which is incorporated herein by reference in its entirety.

The implementations can be further described using the following clauses.

1. A spectral feature control apparatus comprising:
a spectral feature selection module including a plurality of prisms arranged in an optical plane and configured to receive and pass an incoming light beam along the optical plane, the plurality of prisms including:
a first prism positioned at an input side of the spectral feature selection module and configured to receive the incoming light beam;
a second prism configured to receive the light beam that exits the first prism, the second prism comprising two or more portions, with each portion configured to enable a distinct bandwidth range of the light beam; and
an activation mechanism configured to move the second prism along a direction relative to the optical plane to thereby select a bandwidth range of the light beam by positioning a specific portion of the second prism in the optical plane.
   2. The control apparatus of clause 1, wherein the two or more portions are stacked over one another with respect to the optical plane.
   3. The control apparatus of clause 1, wherein the spectral feature selection module is configured to select a wavelength of the light beam in the deep ultraviolet (DUV) range.
   4. The control apparatus of clause 1, further comprising a first actuator configured to rotate the first prism.
   5. The control apparatus of clause 4, wherein rotation of the first prism thereby modifies an optical magnification of the light beam.
   6. The control apparatus of clause 4, wherein the first actuator is configured to rotate the first prism in a range of angles and the activation mechanism is configured to move the second prism to thereby adjust the optical magnification of the light beam in a range of about 10× to about 50×.
   7. The control apparatus of clause 6, wherein adjustment of the optical magnification of the light beam in the range between about 10× and about 50× thereby adjusts the bandwidth of the light beam in the range between about 1000 femtometers (fm) and about 250 fm.
   8. The control apparatus of clause 4, wherein the first actuator includes one or more of a motor, valve, pressure-controlled device, piezoelectric device, linear motor, hydraulic actuator, and voice coil.
   9. The control apparatus of clause 1, wherein the second prism includes a first portion stacked over a second portion, with the first portion, when positioned in the optical plane, configured to interact with a higher range of bandwidths of the light beam, and the second portion, when positioned in the optical plane, configured to interact with a lower range of bandwidths of the light beam.
   10. The control apparatus of clause 9, wherein the first portion has a first geometry and the second portion has a second geometry that is different from the first geometry.
   11. The control apparatus of clause 9, wherein the first portion being positioned in the optical path enables the optical magnification of the light beam in the range between about 10× to about 19×, and the second portion being positioned in the optical path enables the optical magnification of the light beam in the range between about 20× to about 50×.
   12. The control apparatus of clause 11, wherein the first portion comprises a first right-angled triangle geometry including one or more dimensions, and the second portion comprises a second right-angled triangle geometry including one or more dimensions that are different from the first right-angled triangle geometry one or more dimensions.
   13. The control apparatus of clause 10, wherein the first portion comprises a wedge prism with at least one surface plane within the optical path, with the surface plane having a uniform and flat geometry.
   14. The control apparatus of clause 10. wherein the first portion comprises a wedge prism with at least one surface plane within the optical path, with the surface plane having a convex or concave geometry.
   15. The control apparatus of clause 2, wherein the activation mechanism being configured to move the second prism along a direction relative to the optical plane comprises moving the second prism perpendicularly to the optical plane to select the bandwidth range of the light beam.
   16. The control apparatus of clause 1, wherein the spectral feature selection module further comprises a third prism and a fourth prism, and a diffractive optical element arranged to interact with the light beam in a Littrow configuration.
   17. The control apparatus of clause 16, wherein adjustment of the first and second prisms primarily modifies at least the optical magnification of the light beam to enable selection of the bandwidth of the light beam.
   18. The control apparatus of clause 17, further comprising:
a third actuator configured to rotate the third prism; and
a fourth actuator configured to rotate the fourth prism,
wherein the rotation of the third and fourth prisms modifies a central wavelength of the light beam.
   19. The control apparatus of clause 18, wherein the third prism and the fourth prism each comprise calcium fluoride or magnesium fluoride.
   20. The control apparatus of clause 19, wherein the third prism and the fourth prism are right-angle triangle prisms.
   21. The control apparatus of clause 1, wherein the two or more portions of the second prism include first and second portions, the first portion comprises a material having a first refractive index and the second portion comprises a material having a second refractive index that is different from the first refractive index.
   22. The control apparatus of clause 1, wherein the two or more portions of the second prism include first and second portions, the first portion comprises a material having a first refractive index and the second portion comprises a material having a second refractive index that is the same as the first refractive index.
   23. The control apparatus of clause 1, wherein the first prism and the second prism each comprise calcium fluoride or magnesium fluoride.
   24. The control apparatus of clause 1, wherein the activation mechanism includes a pneumatic actuator or an electromechanical actuator.
   25. A method for controlling a wavelength and bandwidth of a light beam produced by an optical oscillator, the method comprising:
selecting a range of bandwidths from a set of distinct ranges of bandwidths including positioning a distinct portion of a second prism in an optical plane through which the light beam travels, wherein the second prism includes a plurality of distinct portions;
controlling the magnification of the light beam produced from the optical oscillator to a desired optical magnification based on the selected range of bandwidths including directing the light beam through a first prism closest to the optical oscillator and through the distinct portion of the second prism positioned in the optical plane;
adjusting an angle at which the light beam travels including directing the light beam through at least a third prism; and
selecting the wavelength and bandwidth of the light beam based on the adjusted angle including impinging the light beam from the at least third prism on a dispersive optical element arranged to interact with the light beam in a Littrow configuration and selecting the wavelength and bandwidth of the light beam based on the optical magnification of the light beam impinging the dispersive optical element.
   26. A deep ultraviolet (DUV) laser system comprising:
a line narrowing module comprising a plurality of prisms such that an incoming laser beam from a laser first interacts with a first prism, then interacts with a second prism after the first prism;
the second prism including two different stacked portions including a first portion designed to interact with higher bandwidths of the incoming laser beam and a second portion designed to interact with lower bandwidths of the incoming laser beam;
the second prism is movable between a first position in which the laser beam interacts with the first portion and a second position in which the laser beam interacts with the first portion;
wherein the second prism is movable by translation using an activation mechanism controlled by a controller to vary a target bandwidth of the laser beam.
   27. The DUV laser system of clause 26, wherein the first portion has a first shape and the second portion has a second shape different than the first shape.
   28. The DUV laser system of clause 26, wherein the activation mechanism is a pneumatic or electric activation mechanism.
   29. An illumination system comprising:
an optical source configured to produce a light beam; and
a spectral feature control apparatus arranged to interact with the light beam produced by the optical source, the spectral feature control apparatus comprising:
a dispersive optical element;
a beam expander including a plurality of prisms arranged in an optical path between the dispersive optical element and an aperture through which the light beam of the optical source can pass, wherein the dispersive optical clement and the beam expander are arranged such that the light beam of the optical source interacts with the aperture, the prisms, and the dispersive optical element along the optical path; and
an activation mechanism configured to move a second prism of the beam expander along a direction that is not parallel with the optical path to select a bandwidth range of the light beam by positioning a specific geometrically-distinct portion of the second prism in the optical path, wherein the second prism is positioned adjacent to a first prism that is closest to the aperture.
The above described implementations and other implementations are within the scope of the following claims.

1. A spectral feature control apparatus comprising:
a spectral feature selection module including a plurality of prisms arranged in an optical plane and configured to receive and pass an incoming light beam along the optical place, the plurality of prisms including:
a first prism positioned at an input side of the spectral feature selection module and configured to receive the incoming light beam;
a second prism configured to receive the light beam that exits the first prism, the second prism comprising two or more portions, with each portion configured to enable a distinct bandwidth range of the light beam; and
an activation mechanism configured to move the second prism along a direction relative to the optical plane to thereby select a bandwidth range of the light beam by positioning a specific portion of the second prism in the optical plane.

2. The control apparatus of claim 1, wherein the two or more portions are stacked over one another with respect to the optical plane.

3. The control apparatus of claim 1, wherein the spectral feature selection module is configured to select a wavelength of the light beam in the deep ultraviolet (DUV) range.

4. The control apparatus of claim 1, further comprising a first actuator configured to rotate the first prism.

5. The control apparatus of claim 4, wherein rotation of the first prism thereby modifies an optical magnification of the light beam.

6. The control apparatus of claim 4, wherein the first actuator is configured to rotate the first prism in a range of angles and the activation mechanism is configured to move the second prism to thereby adjust the optical magnification of the light beam in a range of about 10× to about 50×.

7. The control apparatus of claim 6, wherein adjustment of the optical magnification of the light bear in the range between about 10× and about 50× thereby adjusts the bandwidth of the light beam in the range between about 1000 femtometers (fm) and about 250 fm.

8. The control apparatus of claim 4, wherein the first actuator includes one or more of a motor, valve, pressure-controlled device, piezoelectric device, linear motor, hydraulic actuator, and voice coil.

9. The control apparatus of claim 1, wherein the second prism includes a first portion stacked over a second portion, with the first portion, when positioned in the optical plane, configured to interact with a higher range of bandwidths of the light beam, and the second portion, when positioned in the optical plane, configured to interact with a lower range of bandwidths of the light beam.

10. The control apparatus of claim 9, wherein the first portion has a first geometry and the second portion has a second geometry that is different from the first geometry.

11. The control apparatus of claim 9, wherein the first portion being positioned in the optical path enables the optical magnification of the light beam in the range between about 10× to about 19×, and the second portion being positioned in the optical path enables the optical magnification of the light beam in the range between about 20× to about 50×.

12. The control apparatus of claim 11, wherein the first portion comprises a first right-angled triangle geometry including one or more dimensions, and the second portion comprises a second right-angled triangle geometry including one or more dimensions that are different from the first right-angled triangle geometry one or more dimensions.

13. The control apparatus of claim 10, wherein the first portion comprises a wedge prism with at least one surface plane within the optical path, with the surface plane having a uniform and flat geometry.

14. The control apparatus of claim 10, wherein the first portion comprises a wedge prism with at least one surface plane within the optical path, with the surface plane having a convex or concave geometry.

15. The control apparatus of claim 2, wherein the activation mechanism being configured to move the second prism along a direction relative to the optical plane comprises moving the second prism perpendicularly to the optical plane to select the bandwidth range of the light beam.

16. The control apparatus of claim 1, wherein the spectral feature selection module further comprises a third prism and a fourth prism, and a diffractive optical element arranged to interact with the light beam in a Littrow configuration.

17. The control apparatus of claim 16, wherein adjustment of the first and second prisms primarily modifies at least the optical magnification of the light beam to enable selection of the bandwidth of the light beam.

18. The control apparatus of claim 17, further comprising:
a third actuator configured to rotate the third prism; and
a fourth actuator configured to rotate the fourth prism,
wherein the rotation of the third and fourth prisms modifies a central wavelength of the light beam.

19. The control apparatus of claim 18, wherein the third prism and the fourth prism each comprise calcium fluoride or magnesium fluoride.

20. The control apparatus of claim 19, wherein the third prism and the fourth prism are right-angle triangle prisms.

21. The control apparatus of claim 1, wherein the two or more portions of the second prism include first and second portions, the first portion comprises a material having a first refractive index and the second portion comprises a material having a second refractive index that is different from the first refractive index.

22. The control apparatus of claim 1, wherein the two or more portions of the second prism include first and second portions, the first portion comprises a material having a first refractive index and the second portion comprises a material having a second refractive index that is the same as the first refractive index.

23. The control apparatus of claim 1, wherein the first prism and the second prism each comprise calcium fluoride or magnesium fluoride.

24. The control apparatus of claim 1, wherein the activation mechanism includes a pneumatic actuator or an electromechanical actuator.

25. A method for controlling a wavelength and bandwidth of a light beam produced by an optical oscillator, the method comprising:
selecting a range of bandwidths from a set of distinct ranges of bandwidths including positioning a distinct portion of a second prism in an optical plane through which the light beam travels, wherein the second prism includes a plurality of distinct portions;
controlling the magnification of the light beam produced from the optical oscillator to a desired optical magnification based on the selected range of bandwidths including directing the light beam through a first prism closest to the optical oscillator and through the distinct portion of the second prism positioned in the optical plane;
adjusting an angle at which the light beam travels including directing the light beam through at least a third prism; and
selecting the wavelength and bandwidth of the light beam based on the adjusted angle including impinging the light beam from the at least third prism on a dispersive optical element arranged to interact with the light beam in a Littrow configuration and selecting the wavelength and bandwidth of the light beam based on the optical magnification of the light beam impinging the dispersive optical element.

26. A deep ultraviolet (DUV) laser system comprising:
a line narrowing module comprising a plurality of prisms such that an incoming laser beam from a laser first interacts with a first prism, then interacts with a second prism after the first prism;
the second prism including two different stacked portions including a first portion designed to interact with higher bandwidths of the incoming laser beam and a second portion designed to interact with lower bandwidths of the incoming laser beam;
the second prism is movable between a first position in which the laser beam interacts with the first portion and a second position in which the laser beam interacts with the first portion;
wherein the second prism is movable by translation using an activation mechanism controlled by a controller to vary a target bandwidth of the laser beam.

27. The DUV laser system of claim 26, wherein the first portion has a first shape and the second portion has a second shape different than the first shape.

28. The DUV laser system of claim 26, wherein the activation mechanism is a pneumatic or electric activation mechanism.

29. An illumination system comprising:
an optical source configured to produce a light beam; and
a spectral feature control apparatus arranged to interact with the light beam produced by the optical source, the spectral feature control apparatus comprising:
a dispersive optical element;
a beam expander including a plurality of prisms arranged in an optical path between the dispersive optical element and an aperture through which the light beam of the optical source can pass, wherein the dispersive optical element and the beam expander are arranged such that the light beam of the optical source interacts with the aperture, the prisms, and the dispersive optical element along the optical path; and
an activation mechanism configured to move a second prism of the beam expander along a direction that is not parallel with the optical path to select a bandwidth range of the light beam by positioning a specific geometrically-distinct portion of the second prism in the optical path, wherein the second prism is positioned adjacent to a first prism that is closest to the aperture.
